(19) United States
(12) Patent Application Publication
(10) Pub. No.: US 2004/0112418 A1
(43) Pub. Date: Jun. 17, 2004

(54) Thermoelectric material using ZrNiSn-based half-Heusler structures

(76) Inventors: Jihui Yang, Lakeshor (CA); Lidong Chen, Shanghai (CN); Gregory Paul Meisner, Ann Arboro, MI (US); Ctirad Uher, Ann Arbor, MI (US)

Correspondence Address: KATHRYN A. MARRA, General Motors Corporation, Legal Staff, Mail Code 482-C23-B21, P.O. Box 300, Detroit, MI, 48265-3000, US

(21) Appl. No.: 10/318,334

(22) Filed: Dec. 12, 2002

(51) Int. Cl. H01L 35/20; H01L 35/00; H01L 37/00; H01L 35/14

(52) U.S. Cl. 136/239; 136/240

(57) ABSTRACT

The present invention provides a thermoelectric material made from the ZrNiSn-based, half-Heusler structure where Pd is alloyed on the site of Ni, Hf alloyed on Zr, and Sb doped on Sn, all in accordance with the formula Zr_{0 5}Hf_{0.5}Ni₁₋ₓPdₓSn_{0.99}Sb_{0 01}. The structure significantly increases the value of the figure of merit (ZT) by decreasing the structure's thermal conductivity, without significant increases to its Seebeck coefficient.

### STATEMENT OF GOVERNMENT SUPPORT

The Government of the United States of America has rights in this invention pursuant to Agreement No. DARPA N00014-98-3-0011.

### TECHNICAL FIELD

This invention relates generally to thermoelectric materials, and more specifically, to a thermoelectric material having a ZrNiSn-based half-Heusler crystal structure that is capable of generating high electrical power at elevated temperatures.

### BACKGROUND OF THE INVENTION

Thermoelectric materials are commonly used for both power generation and cooling processes. Thermoelectric technology has been used for power generation in NASA's interplanetary spaceships and for cooling solid state lasers and infrared detectors. The Seebeck Effect and the Peltier Effect are the foundations for modern thermoelectric power generation and cooling, respectively. In each application thermoelectric materials are used in an electrical circuit between a high temperature junction and a low temperature junction. In the case of thermoelectric power generation, the temperature difference between the junctions is utilized to generate electrical energy, whereas in thermoelectric cooling, electrical energy is used to transfer heat from the cold junction to the hot junction.

The efficiency of a thermoelectric material is often characterized by a thermoelectric figure of merit, ZT. ZT is a dimensionless product and is defined by:

$$Z T = \frac{{S}^{2} T}{ρ κ} = \frac{{S}^{2} T}{ρ ( {κ}_{L} + {κ}_{e} )}$$

where S, ρ, κ, κL, κe, and T are the Seebeck coefficient (or thermopower), electrical resistivity, total thermal conductivity, lattice thermal conductivity, electronic thermal conductivity, and absolute temperature, respectively. An efficient thermoelectric material possesses a combination of a high Seebeck coefficient, low electrical resistivity, and low thermal conductivity. Thus, the figure of merit, ZT, brings together physical properties that are necessary for a useful thermoelectric material.

The Seebeck effect is observed when two dissimilar materials are electrically connected to form a circuit with two junctions, maintained at different temperatures. In this arrangement, the temperature difference results in usable electrical potential, i.e., a voltage. Often, the dissimilar materials include an n-type and a p-type semiconductor material to make a thermoelectric generator. Recent studies (e.g., U.S. Pat. No. 6,342,668) have shown certain skutterudite materials to be highly efficient p-type materials for relatively high temperature thermoelectric applications. And ZrNiSn-based alloys have shown promise as suitable n-type thermoelectric materials for high temperature applications. The ZrNiSn-based alloys are candidates for use with the skutterudites in thermoelectric generators for automotive waste heat recovery, since both have optimum operation temperatures in the same range as the exhaust gases. The temperature range of interest centers on about 800 K.

Current state-of-the-art thermoelectric materials are Bi₂Te₃, PbTe, and Ge-based mixed crystals. These materials have ZT values of about 1 in their optimum operational temperatures. But these ranges are either well above or below 800 K, the temperature of interest for use of automotive exhaust heat. The recently discovered skutterudite-based compounds have the highest reported ZT value of about 1.4 around a temperature of 800 K. But a suitable n-type material is needed for the thermoelectric power conversion combination.

Recent discoveries using ZrNiSn-based compositions in half-Heusler crystal structures have produced ZT values of the order of 0.5 at 800 K but with the promise of achieving higher levels. Transport studies have established that half-Heusler compounds of this family of compositions exhibit band gaps of about 0.21-0.24 eV, which suggest a very high value of thermopower as a consequence of the narrow band gap and the heavy carrier mass. These are promising characteristics of a good thermoelectric material.

Exploration of the transport properties of the half-Heusler inter-metallic structure has offered significant promise for further increases in ZT at 800 K. Combinations having ZrNiSn-based, half-Heusler lattice structures have been tested and reported. These materials included ZrNiSn, ZrNiSn_{0 99}Sb_{0 01}, and Zr_{0 5}Hf_{0.5}NiSn_{0.99}Sb_{0.01}. Currently, ZrNiSn-based, half-Heusler structures exhibit values of ZT of 0.5 at 800 K, which is much lower than the companion p-type material. As such, there remains a need for more effective n-type thermoelectric materials at about 800 K.

Thus, it is an object of the present invention to provide a thermoelectric material having a specific combination of elements in a half-Heusler crystal lattice structure that has a figure of merit, ZT, in excess of 0.5 at temperatures centering on 800 K.

### SUMMARY OF THE INVENTION

The present invention provides an improved thermoelectric material having a ZrNiSn-based, half-Heusler crystal lattice structure conforming to a composition of Hf_{0 5}Zr_{0 5}Ni₁₋ₓPdₓSn_{0.99}Sb_{0 01}. The substitution of Pd for some Ni in the overall combination creates mass defects in the crystal lattice, thereby decreasing the lattice thermal conductivity of the family of compounds. For example, the Zr_{0 5}Hf_{0.5}Ni_{0.5}Pd_{0 5}Sn_{0 99}Sb_{0 01} sample has the lowest room temperature thermal conductivity, i.e., 3.1 W/m-K, among any reported values of the ZrNiSn-based half-Heusler compounds. Such a reduction in a factor of the denominator of the ZT equation is necessary and useful in the development of current thermoelectric materials. The substitution of palladium for nickel in this combination also has led to an increase in the overall thermoelectric properties. One member of the family, Hf_{0 5}Zr_{0.5}Ni_{0 8}Pd0.2Sn_{0 99}Sb_{0 01}, has a ZT at 800 K of 0.7.

There is a need for such high temperature thermoelectric materials in automotive applications, for example, in capturing electrical power from exhaust gas or radiator heat and using it for automotive accessories, such as a radio or a telephone. Moreover, thermoelectric technology is advantageous because of its solid state operation, high reliability, long life, and low noise and vibration levels. The half-Heusler materials conforming to a composition of Hf_{0 5}Zr_{0 5}Ni₁₋ₓPdₓSn_{0.99}Sb_{0.01} provide useful improvements in such materials

These and other objects and advantages of this invention will become apparent from a detailed description of the preferred embodiment that follows.

### BRIEF DESCRIPTION OF THE DRAWINGS

FIG. 1 is a schematic diagram of a ZrNiSn-based, half-Heusler crystal lattice unit cell structure.

FIG. 2 is a graph showing the temperature dependence of the electrical resistivity of the ZrNiSn-based, half-Heusler compounds tested.

FIG. 3 is a graph showing the temperature dependence of the thermal conductivity of ZrNiSn-based, half-Heusler compounds tested.

FIG. 4 is a graph showing the temperature dependence of the Seebeck coefficient for the ZrNiSn-based, half-Heusler compounds tested.

FIG. 5 is a graph showing the temperature dependence of the power factor of the ZrNiSn-based, half-Heusler compounds tested.

FIG. 6 is a graph showing the thermoelectric figure of merit (ZT) for all samples tested at temperatures between 300 K and 1000 K.

### DESCRIPTION OF THE PREFERRED EMBODIMENT

As stated, this invention provides improvement in the thermoelectric properties of n-type semiconductor materials built on variations in ZrNiSn-based, half-Heusler structure materials. In these half-Heusler, Hf_{0.5}Zr_{0.5}Ni₁₋ₓPdₓSn_{0.99}Sb_{0 01} compositions, it is believed that the improvement of ZT is mainly due to the mass defects introduced by substitution of palladium for some of the nickel. A schematic illustration of the ZrNiSn-based, half-Heusler structure may be helpful. Such an illustration will also schematically show how the Hf, Pd and Sb atoms fit into the structure.

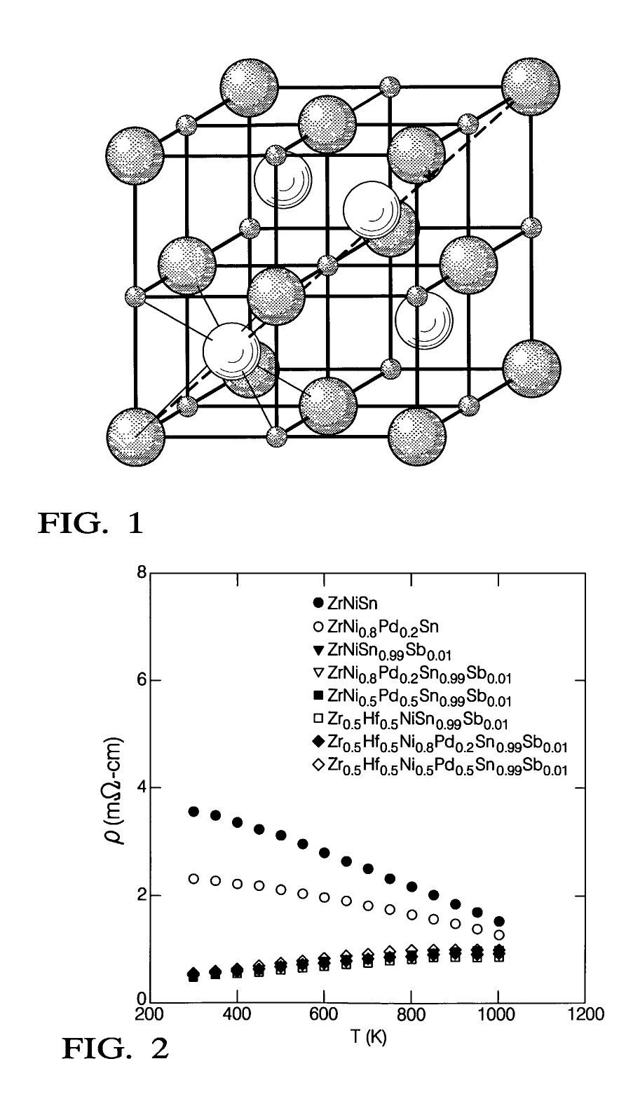

A general schematic of a single unit cell of a ZrNiSn-based, half-Heusler structure is shown in FIG. 1. In general, half-Heusler compounds are a subset of a much larger family of compounds possessing the MNi₂Sn type structure. These structures, known as Heusler structures, comprise four filled, interpenetrating, face-centered cubic (fcc) sub-lattice structures. A half-Heusler structure, however, comprises three filled and one vacant interpenetrating fcc sub-lattices and has one half of the number of Ni atoms as that of the full Heusler structure.

The known ZrNiSn-based, half-Heusler crystal structure is designated as an F43m space group structure with four non-equivalent four-fold sites. A portion of the structure is illustrated in FIG. 1 as a schematic unit cell in which the Zr sites are represented by large gray-filled spheres, the Ni sites are represented by small gray filled spheres and the Sn sites are represented by large unfilled spheres. In this illustration, the Zr sites are easily perceived as lying in a face centered cubic arrangement in the unit cell. The Ni sites are also seen in this illustration to be located in an offset, inter-penetrating face centered cube. While the Sn sites also lie in a fcc arrangement in the half-Heusler structure, that arrangement is not easily perceived in the FIG. 1 illustration. FIG. 1 does show that the Sn sites are centered between surrounding neighboring Zr and Ni sites as shown by the intersecting solid lines drawn between Zr and Ni sites in the lower left front corner of the unit cell cube of FIG. 1. The Sn sites fill some, but not all, of the vacancies between such Zr and Ni sites. For example, a dashed line body diagonal is drawn in FIG. 1 between the lower left front Zr site and the upper right rear Zr site. Going up from the lower Zr site, the body diagonal passes through the lower front Sn site, the central Ni site and a vacancy between the central Ni site and the upper right rear Zr site. The lower front Sn site, the central Ni site and the vacancy are spaced at intervals of one-quarter of the total body diagonal.

There are equal numbers of Zr, Ni and Sn atoms in this half-Heusler material. FIG. 1 is consistent with this composition because each cube corner Zr site is shared with 8 such adjacent unit cells, and each cube face centered Zr site is shared by 2 adjacent unit cells. The Ni sites positioned on the faces of the unit cell cube are also shared by adjacent cells.

In accordance with this invention, Hf atoms are randomly substituted at half the Zr sites and Sb atoms are randomly substituted (doped) at one percent of the Sn sites. Further in accordance with the invention, Pd atoms are randomly substituted on some and up to half of the Ni sites. Preferably, Pd atoms are substituted in 20 to 50 atomic % of the Ni sites. In the compound with the highest ZT, Pd atoms are substituted at 20 atomic % of the Ni sites.

Several ZrNiSn-based structures were tested, including structures exemplifying the present invention. These materials included ZrNiSn, ZrNiSn_{0.99}Sb_{0.01}, Zr_{0 5}Hf_{0.5}NiSn_{0.99}Sb_{0 01}, ZrNi_{0.8}Pd_{0.2}Sn, ZrNi_{0.8}Pd_{0 2}Sn_{0.99}Sb_{0.01}, ZrNi_{0 5}Pd_{0 5}Sn_{0 99}Sb_{0.01}, Zr_{0 5}Hf_{0 5}Ni_{0 8}Pd_{0 2}Sn_{0.99}Sb_{0 01}, and Zr_{0.5}Hf_{0.5}Ni_{0 5}Pd_{0 5}Sn_{0 99}Sb_{0.01}. These were prepared by a solid state reaction method. High quality samples can also be made by combining arc melting and annealing methods. To prepare these samples, a powder mixture of high purity elemental constituents were heated to 1173 K under a flowing argon atmosphere for about 96 to 168 hours. The powders, at 1173 K, were then consolidated using a spark plasma sintering technique for 25 minutes.

In accordance with this invention the use of equal atomic proportions of hafnium and zirconium is considered essential. It is also considered essential to dope the tin with one atomic percent antimony. The beneficial properties of this invention further result from substituting palladium for some, but not all, of the nickel in the stated combination of Hf, Zr, Sn and Sb. The other half-Heusler materials that were made were used for comparison of the tested physical properties.

Thermoelectric properties, specifically the thermal conductivity, of each compound was measured using a laser flash technique (Shinkuriko: TC-7000™) in vacuum over a temperature range of 300-1000 K. Graphite and stainless steel specimens were used as standard samples for calibration. By means of X-ray powder diffraction and electron microprobe analysis, all samples produced were of single phase and stoichiometric.

As shown above, a key to obtaining a high figure of merit is to make a thermoelectric material that exhibits a low thermal conductivity (κ) and low electrical resistivity (ρ), while maintaining a rather high Seebeck coefficient (S).

The samples that were made were each tested for such properties. As a first test, the temperature dependence of the electrical resistivity of the ZrNiSn-based, half-Heusler compounds was determined and is shown in FIG. 2. For the two undoped (non-Sb containing) samples, ZrNiSn and ZrNi_{0 8}Pd_{0 2}Sn, the electrical resistivity decreases with increasing temperature over the entire temperature range, which is typical of activated behavior. Doping 1 atomic % of Sb on the Sn site reduces the room temperature electrical resistivity by a factor of 4 to 6 and markedly changes the temperature dependence of the electrical resistivity from an activated behavior to a metal-like one.

The electrical resistivities of the four antimony-doped samples are very similar to one another and, together, are smaller than the electrical resistivities of the undoped samples over the entire temperature range. As temperature increases, the electrical resistivity approaches a common value. As such, half-Heusler structures having the compositions Zr_{0 5}Hf_{0 5}NiSn_{0.99}Sb_{0.01}, Zr_{0 5}Hf_{0.5}N_{0.8}Pd_{0 2}Sn_{0.99}Sb_{0.01}, and Zr_{0.5}Hf_{0 5}Ni_{0.5}Pd_{0.5}Sn_{0.99}Sb_{0 01} provide the lowest electrical resistivities at room temperature, thereby making these compositions most promising for better thermoelectric performance. Substituting palladium for nickel did not significantly lower the resistivity of the hafnium free and undoped sample.

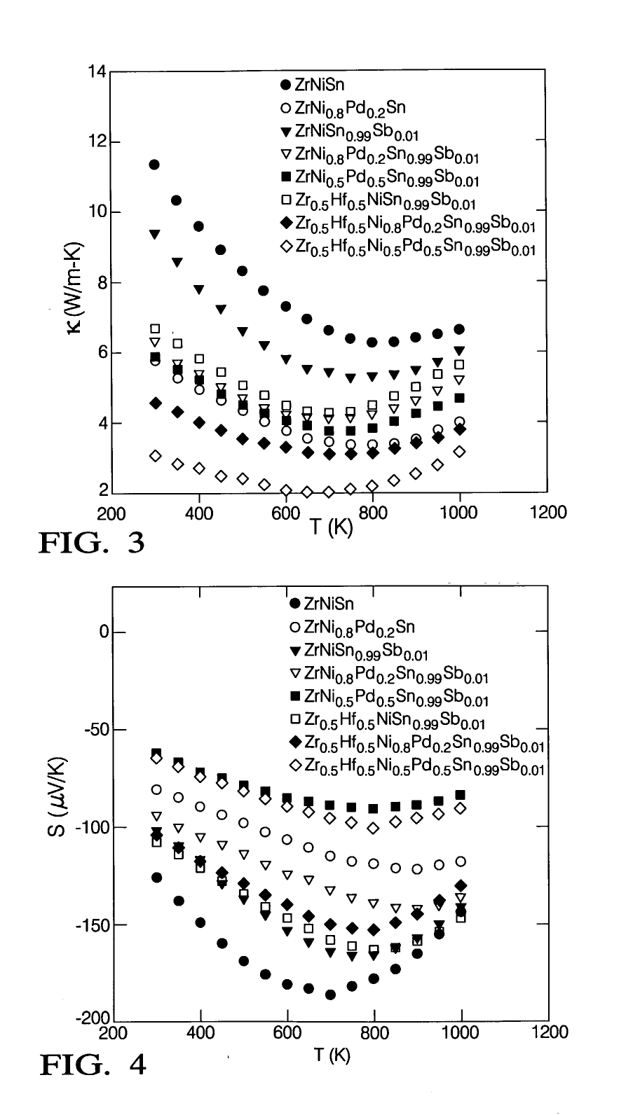

Total thermal conductivity (κ) is a measure of how well a material conducts heat. Since ZT is inversely proportional to the material's total thermal conductivity (as seen by the equation above), it is clear that a reduction in thermal conductivity can result in higher ZT values. As a second test, the temperature dependence on thermal conductivity of the samples was determined and is shown in FIG. 3.

It is known that the ZrNiSn structure has a room temperature thermal conductivity of between 10 W/m-K and 15 W/m-K. As shown in FIG. 3 the total thermal conductivity drops from 11-12 W/m-K at 300 K to about 7 W/m-K at 600 to 1000 K. Alloying on the Zr site evidently reduces the room temperature thermal conductivity to a value of about 6 W/m-K. After noticing the improvement in lower thermal conductivity, experimentation lead to even further reductions by substituting Pd on the Ni site.

Starting with the basic ZrNiSn-based half-Heusler structure, 20 atomic % of Pd was alloyed on Ni site (i.e., ZrNi_{0.8}Pd_{0.2}Sn). A reduction of the thermal conductivity, by about a factor of two over the entire temperature range tested, was found. Being that the ZrNiSn_{0 99}Sb_{0.01}, i.e., a doped sample, exhibited a lower thermal conductivity than the ZrNiSn-based structure, alloying Pd on Ni site of a doped sample was thought to further reduce the thermal conductivity. As such, the ZrNi_{0.8}Pd_{0 2}Sn_{0 99}SB_{0.01} material exhibited an even lower thermal conductivity than before (i.e., about 6.2 W/m-K at room temperature).

Following this line of logic, even further reductions in thermal conductivity was found by alloying 50 atomic % of Pd on Ni site, while doping 1 atomic % Sb on Sn site (i.e., ZrNi_{0 5}Pd_{0.5}Sn_{0 99} Sb_{0 01}). These substitutions provided a thermal conductivity value of about 6 W/m-K.

Substitution of 50 atomic % of Hf on Zr site can further reduce the thermal conductivity of the material. As a result, the thermal conductivities of Zr_{0.5}Hf_{0 5}Ni_{0.8}Pd_{0.2}Sn_{0 99}Sb_{0 01} and Zr_{0.5}Hf_{0 5}Ni_{0.5}Pd₀₅Sn_{0 99}Sb_{0.01} were found to be 4.5 W/m-K and 3.1 W/m-K at room temperature, respectively. The low thermal conductivity values achieved for the Zr_{0 5}Hf_{0 5}Ni_{0.8}Pd_{0 2}Sn_{0 99}Sb_{0 01} and Zr_{0 5}Hf_{0 5}Ni_{0 5}Pd₀₅Sn_{0 99}Sb_{0 01} samples of this invention is beneficial. This characteristic coupled with their low electrical resistivity values have demonstrated the benefit of substituting Pd on Ni site in a ZrNiSn-based half-Heusler structure also having 50 atomic % Hf alloyed on Zr site and 1 atomic % Sb doped on Sn site.

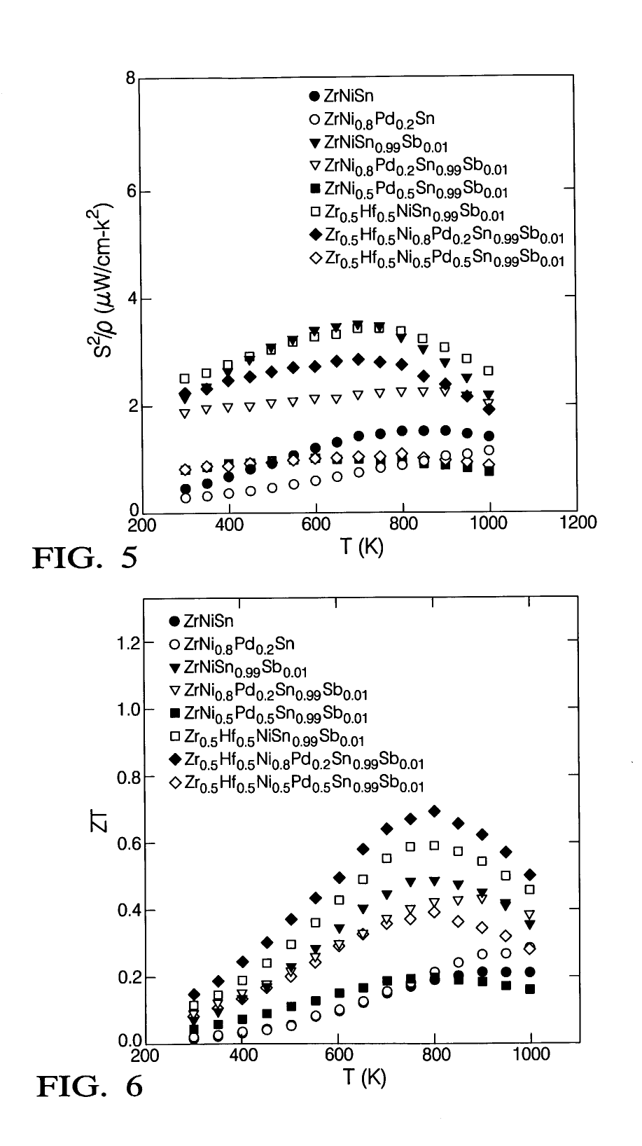

As a third test, the temperature dependence on the Seebeck coefficient was determined and is shown in FIG. 4. Comparing the two half-Heusler structure examples of this invention with the highest potential for increased figures of merit (i.e., Zr_{0.5}Hf_{0 5}Ni_{0.8}Pd_{0.2}Sn_{0 99}Sb_{0.01} and Zr_{0 5}Hf_{0 5}Ni_{0.5}Pd_{0.5}Sn_{0 99}Sb_{0 01}), a higher Seebeck coefficient was found for the Zr_{0.5}Hf_{0 5}Ni_{0 8}Pd_{0.2}Sn_{0.99}Sb_{0 01} structure, which is due to the heavy electron mass of the conduction band. Although the ZrNiSn and Zr_{0 5}Hf_{0.5}NiSn_{0.99}Sb_{0.01} structure exhibits even higher Seebeck coefficients, their thermal conductivity values are much too high to significantly increase the figure of merit, ZT. Thus, FIG. 5 illustrates that the Seebeck coefficient alone does not quantify the thermoelectric merit of a candidate thermoelectric material. The six element, palladium-nickel containing combinations of this invention provide a high ZT material and others with very low thermal conductivity.

As a fourth test, the temperature dependence of the power factor, S²/ρ for all the samples tested were determined and now shown in FIG. 5. Large values of power factor (i.e., over 20 W/cm-K²) were observed for a number of Sb-doped samples covering the whole temperature range tested. A maximum power factor value was found for ZrNiSn_{0 99}Sb_{0.01} and that value was 34.4 W/cm-K². However, the power factor is only a part of ZT. Thermal conductivity is also a significant factor. As will be seen, the six element thermoelectric material combinations of this invention provide unique materials that display high figures of merit.

The thermoelectric figure of merit, ZT, for all samples tested, is shown in FIG. 6. A ZT value for the Zr_{0 5}Hf_{0.5}Ni_{0 8}Pd_{0 2}Sn_{0 99}Sb_{0.01} structure was observed at about 0.15 at room temperature and about 0.7 at 800 K. As seen from FIG. 6, the ZT values for the Zr_{0.5}Hf_{0 5}Ni_{0 8}Pd_{0 2}Sn_{0.99}Sb_{0.01} compound are the highest along the entire temperature range as compared to all of the other ZrNiSn-based compounds tested. Furthermore, the ZT values obtained for the Zr_{0.5}Hf_{0.5}Ni_{0.8}Pd_{0.2}Sn_{0.99}Sb_{0 01} structure are the highest ZT values over the temperature range tested for any half-Heusler compounds reported in literature thus far.

Thus, the Zr_{0.5}Hf_{0 5}Ni₁₋ₓPdₓSn_{0.99}Sb_{0.01} composition, half-Heusler materials of this invention advance the art of n-type thermoelectric materials, especially for high temperature applications of about 800 K. One material, Zr_{0 5}Hf_{0.5}Ni_{0.8}Pd_{0 2}Sn_{0 99}Sb_{0 01}, provides the highest ZT value in this range and the others provide combinations of low thermal conductivity and electrical resistivity.

While the invention has been described in terms of a preferred embodiment, it is not intended to be limited to that description, but rather only to the extent of the following claims.

1. A thermoelectric material of the composition Zr_{0 5}Hf_{0 5}Ni₁₋ₓPdₓSn_{0.99}Sb_{0 01} and having a ZrNiSn-based, half-Heusler crystal lattice structure conforming to a space group of F43m.

2. A thermoelectric material of the composition Z_{0.5}Hf_{0.5}Ni_{[0.5-0.8]}Pd_{[0.2-0.5]}Sn_{0 99}Sb_{0 01} and having a ZrNiSn-based, half-Heusler crystal lattice structure conforming to a space group of F43m.

3. A thermoelectric material of the composition Zr_{0 5}Hf_{0.5}Ni_{0.8}Pd_{0.2}Sn_{0.99}Sb_{0 01} and having a ZrNiSn-based, half-Heusler crystal lattice structure conforming to a space group of F43m.

4. A thermoelectric material as recited in claim 3 wherein said ZrNiSn-based structure possesses a figure of merit (ZT) value of about 0.7 at a temperature of about 800 K.
